(19) United States
(12) Patent Application Publication
(10) Pub. No.: US 2007/0277958 A1
(43) Pub. Date: Dec. 6, 2007

(54) Heat Dissipator

(76) Inventor: Yi-He Huang, Chung-Ho City (TW)

Correspondence Address: HDSL, 4331 STEVENS BATTLE LANE, FAIRFAX, VA, 22033, US

(21) Appl. No.: 11/421,546

(22) Filed: Jun. 1, 2006

(51) Int. Cl. H05K 7/20

(52) U.S. Cl. 165/80.3; 361/697; 165/121; 165/104.33

(57) ABSTRACT

A heat dissipator for mounting on a heat-generating element includes a heat-dissipating body, a fan assembly, a bottom stand and a top stand. The heat-dissipating body is formed into a spherical body and constituted of a plurality of heat-dissipating pieces. The heat-dissipating body is provided with a sealed accommodating space therein for accommodating the fan assembly. Further, the bottom stand and the top stand are provided at the upper and lower ends of the heat-dissipating body, respectively. Further, the bottom of the fan assembly has a connecting seat for connecting to the bottom stand to fix the fan assembly. Finally, the bottom stand is provided with a heat-conducting block for adhering to the heat-generating element, thereby to conduct the heat generated by the operation of the heat-generating element to the heat-dissipating body. In this way, the heat can be uniformly dissipated to each heat-dissipating piece. With the airflow generated by the fan assembly, the heat-dissipating effect can be satisfactorily achieved.

### BACKGROUND OF THE INVENTION

1. Field of the Invention

The present invention relates to a heat dissipator, and in particular to a structure of the heat dissipator having a fan.

2. Description of Prior Art

Owing to the tendency to pursue a small-sized and light device, the heat generated by the device is inevitably increased to a great extent. In order not to influence the operation of the electronic element by the increasing temperature resulted from the heat source, the heat-dissipating effect should be increased accordingly. Therefore, a technical measure that is most widely used is to directly mount the heat-dissipating device on the heat-generating element, thereby to improve the heat-dissipating performance with respect to the heat-generating element.

The most common measure in prior art is to use a fan. With the rotation of the blades of the fan, the air around the heat-generating element flows rapidly to carry away the heat generated by the operation of the heat-generating element. In this way, the heat-dissipating effect can be achieved. However, such heat-dissipating effect is restricted because the effective area for heat dissipation is limited to the contacting surfaces between the heat-generating element and the fan. As a result, the heat-dissipating effect is insufficient and thus the heat-dissipating performance of the fan is greatly affected.

In a subsequent measure, the insufficient heat-dissipating area of the heat-generating element is supplemented by using a plurality of heat-dissipating fins or aluminum extrusions made of materials having high heat conductivity to directly adhere onto the heat-generating element. In this way, the heat-dissipating area of the heat-generating element can be enlarged to improve the heat-dissipating efficiency. Finally, with the air-cooling action of the fan, the heat generated by the heat-generating element can be completely dissipated.

In the above-mentioned measure, the material having high heat conductivity is used as the medium for enlarging the heat-dissipating area so as to improve the heat-dissipating efficiency. However, owing to the restriction caused by the space arrangement of the heat-generating element so as to save the space of the heat dissipator of the fan, an open groove is directly provided on the heat-dissipating body constituted of a plurality of heat-dissipating pieces. Further, the fan is directly mounted in the groove. The operation of the fan facilitates the air around the heat-dissipating pieces to flow, thereby to improve the heat-dissipating efficiency thereof. However, in the above-mentioned heat-dissipating structure, the fan is located at the topmost of the heat-dissipating fins or the aluminum extrusions to blow the air downwardly. Due to the square structure of the plurality of heat-dissipating pieces, it affects the convention of the air generated by the fan, so that the air having absorbed heat cannot be rapidly guided to the outside. As a result, the hot air blocks within the heat dissipator and thus cannot improve the heat dissipation efficiently, which becomes the drawback of such heat-dissipating device.

In view of the above, the inventor proposes the present invention to overcome the above problems based on his expert experiences and deliberate researches.

### SUMMARY OF THE INVENTION

In view of the above drawbacks, the present invention is to provide a heat dissiptor for mounting on a heat-generating element. By using a heat-dissipating body with a spherical structure for enlarging the heat-dissipating area and arranging the fan within the heat-dissipating body, the heat-dissipating area can be enlarged to improve the heat-dissipating efficiency. In addition, the airflow generated by the fan can be flown downwardly to facilitate the heat-dissipating action of the heat dissipator.

The present invention provides a heat dissipator comprising a heat-dissipating body, a fan assembly, a bottom stand and a top stand. The heat-dissipating body is formed into a spherical body and constituted of a plurality of heat-dissipating pieces. The heat-dissipating body is provided with a sealed accommodating space therein for accommodating the fan assembly. Further, the bottom stand and the top stand are provided at the upper and lower ends of the heat-dissipating body, respectively. The bottom stand and the top stand are constituted of two identical sub-stands. Further, the bottom of the fan assembly has a connecting seat for connecting to the bottom stand to fix the fan assembly. Finally, the bottom stand is provided with a heat-conducting block for adhering to the heat-generating element, thereby to conduct the heat generated by the operation of the heat-generating element to the heat-dissipating body. In this way, the heat can be uniformly dissipated to each heat-dissipating piece. With the airflow generated by the fan assembly, the heat-dissipating effect can be satisfactorily achieved.

### BRIEF DESCRIPTION OF THE DRAWINGS

The features of the invention believed to be novel are set forth with particularity in the appended claims. The invention itself however may be best understood by reference to the following detailed description of the invention, which describes certain exemplary embodiments of the invention, taken in conjunction with the accompanying drawings in which:

FIG. 1 is an exploded perspective view showing the structure of the present invention;

FIG. 2 is a perspective view showing the structure of the present invention;

FIG. 3 is a side view showing the operation of the structure of the present invention;

FIG. 4 is a schematic view showing the structure of the heat dissipator according to another embodiment of the present invention;

FIG. 5 is a schematic view showing the structure of the a further embodiment of the present invention; and

FIG. 6 is a schematic view showing the structure of the heat dissipator according to still another embodiment of the present invention.

### DETAILED DESCRIPTION OF THE INVENTION

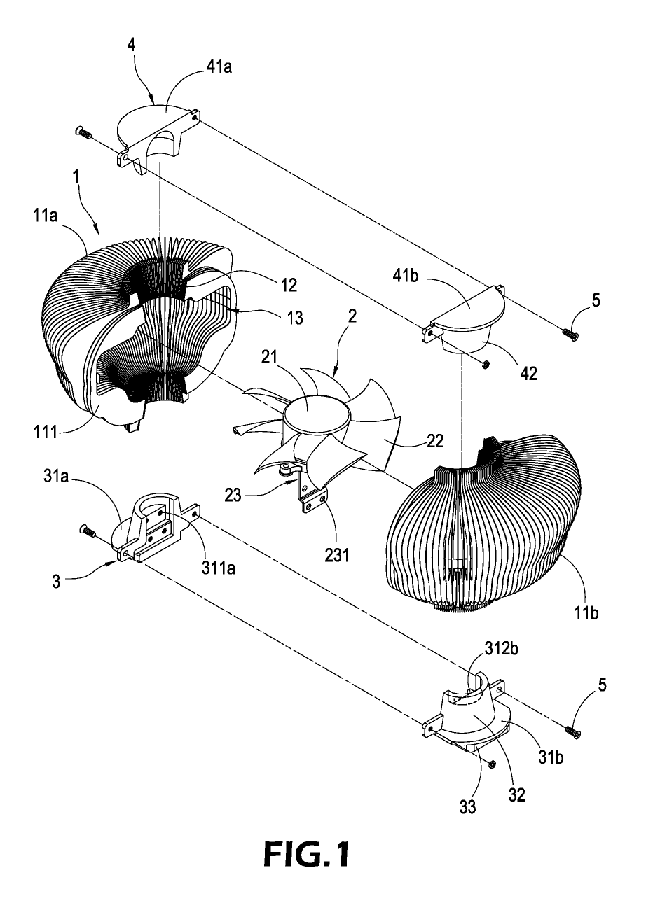

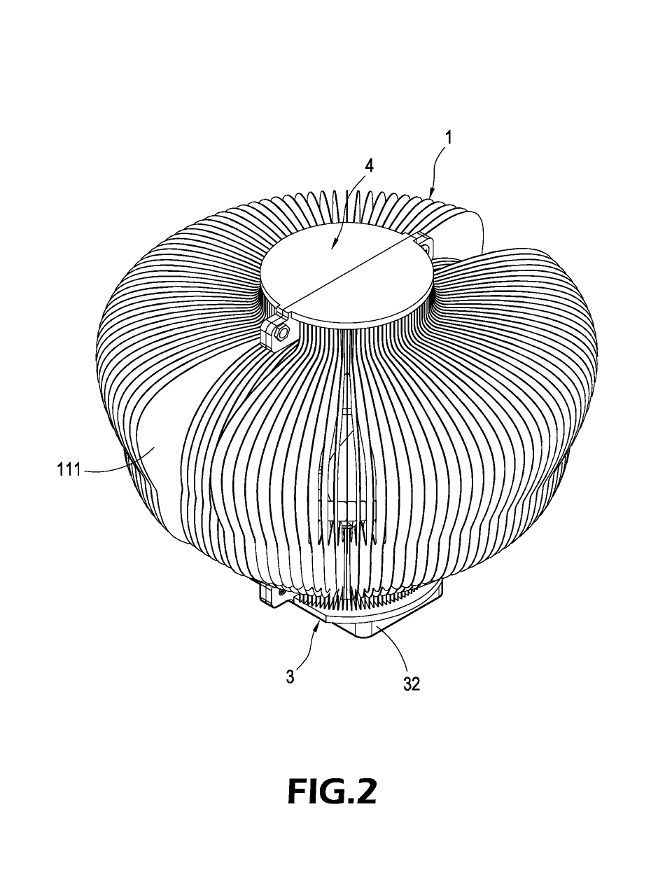

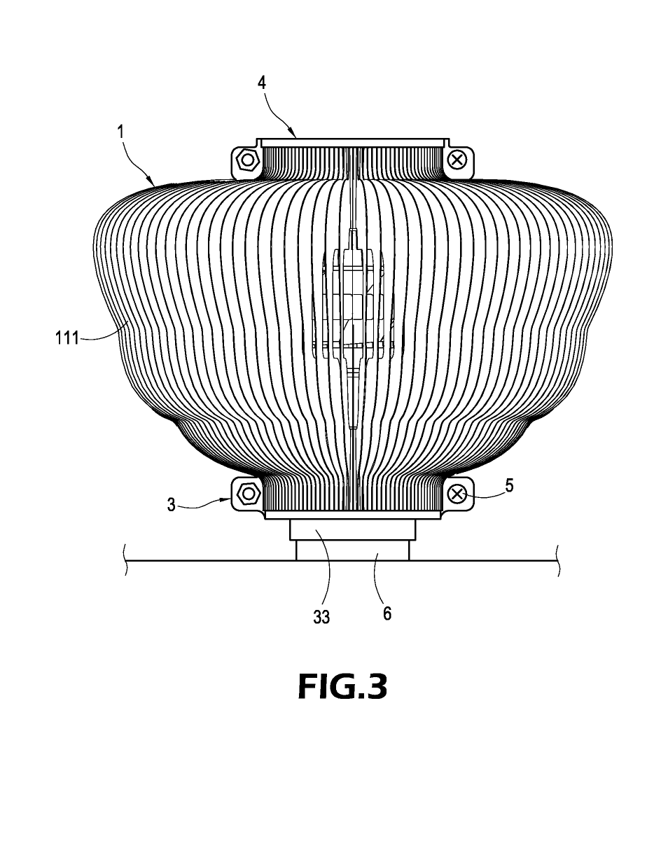

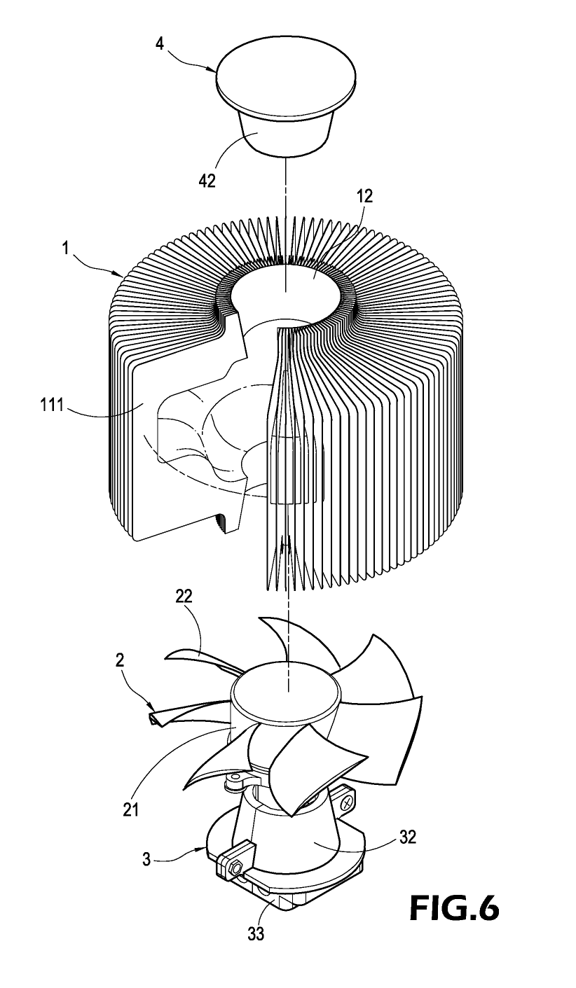

With reference to FIG. 1, it is an exploded perspective view showing the structure of the present invention. It can be seen from the drawing that the heat dissipator of the present invention mainly comprises a heat-dissipating body 1, a fan assembly 2, a bottom stand 3 and a top stand 4. The heat-dissipating body 1 is constituted of two semi-spherical bodies 11a and 11b. The upper and lower ends of the heat-dissipating body 1 are correspondingly formed with a hollow connecting portion 12. The semi-spherical bodies 11a and 11b are formed by means of welding (or bonding) a plurality of heat-dissipating pieces 111 together. The outer periphery of each heat-dissipating piece 111, as seen from its side, is formed into a curved shape (or rectangular, as shown in FIG. 6), while bending outwardly at the inner periphery of each heat-dissipating piece 111 of the semi-spherical bodies 11a and 11b. After the semi-spherical bodies 11a and 11b are combined with each other to form the heat-dissipating body 1, a spherical accommodating space 13 is sealed within the heat-dissipating body 1. Alternatively, both semi-spherical bodies 11a and 11b of the heat-dissipating body 1 can be integrally formed to one piece. Further, the fan assembly 2 is disposed in the accommodating space 13 formed within the heat-dissipating body 1 to blow the air downwardly. The fan assembly 2 has a casing 21 in which the electronic elements (not shown because they are so conventional that the description thereof is omitted) necessary for operating the fan assembly 2 are provided. The periphery of the casing 21 is provided with a plurality of blades 23. A connecting seat 23 extends from the bottom of the casing 21. The connecting seat 23 is provided with a plurality of positioning holes 231 thereon for connecting to the bottom stand 3 to fix the fan assembly 2 (later described). The fan assembly 2 is electrically connected to an external power source for operation. Further, the bottom stand 3 is constituted of two corresponding sub-stand 31a and 31b fixed by fastening elements 5 (such as screws shown in the drawing). The bottom stand 3 is made of a material having high heat conductivity. Further, after assembling the sub-stands 31a and 31b, the assembled bottom stand 3 has a connecting pillar 32 for correspondingly connecting to the connecting portion 12 provided on the bottom of the heat-dissipating body 1 and are also fixedly connected with each heat-dissipating piece 111 of the heat-dissipating body 1. The sub-stand 31a is further provided with a plurality of holes 311a, whereas the sub-stand 31b is provided with a plurality of protruding posts 312b for corresponding to the plurality of holes 311a in positions. Therefore, with the protruding posts 312 of the sub-stand 31b penetrating through the positioning holes 231 and the holes 311a, the connecting seat 23 of the fan assembly 2 can be sandwiched in the bottom stand 3. In this way, the fan assembly 2 can be fixed into the heat-dissipating body 1. Further, the bottom of the bottom stand 3 is provided with a heat-conducting block 33 for adhering to the heat-generating element 6 (FIG. 3). Finally, the top stand 4 is disposed into the connecting portion 12 on the top of the heat-dissipating body 1. The top stand 4 is also made of a material having high heat conductivity and is constituted of two sub-stands 41a and 41b whose shapes correspond to each other. With fastening elements 5 (such as screws shown in the drawing), these two sub-stands can be fixed together. After the sub-stands 41a and 41b are assembled, a connecting pillar 42 is formed to connect to the upper end of the connecting portion 12 of the heat-dissipating body 1 and also connect to the plurality of heat-dissipating pieces 111. In this way, the heat-dissipating pieces 111 can be fixed. FIG. 2 shows the structure of the heat dissipator after the completion of assembling. Alternatively, the bottom stand 3 and the top stand 4 can be integrally formed into one piece.

With reference to FIG. 3, it is a schematic view showing the operation of the present invention. In the heat dissipator of the present invention, the heat-conducting block 33 on the bottom stand 3 is used to directly adhere to the heat-generating element 6, so that the heat generated by the operation of the heat-generating element 6 can be conducted to the bottom stand 3 with the heat conduction of the heat-conducting block 33. Further, with the plurality of heat-dissipating pieces 111 connected to the base stand 3, the absorbed heat can be further dissipated uniformly. At the time of the heat exchange between the heat-dissipating pieces 111 and the outside cool air, the blades 22 of the fan assembly 2 provided within the heat-dissipating body 1 rotate to generate airflow, thereby to facilitate the air around the heat-dissipating pieces 111 to flow. As a result, the heat-dissipating efficiency of the air-cooling action can be improved. Also, the hot air having absorbed the heat will be blown to a farther place, which prevents the hot air to raise the temperature of the air around the heat-generating element 6 to affect the heat-dissipating performance of the heat dissipator.

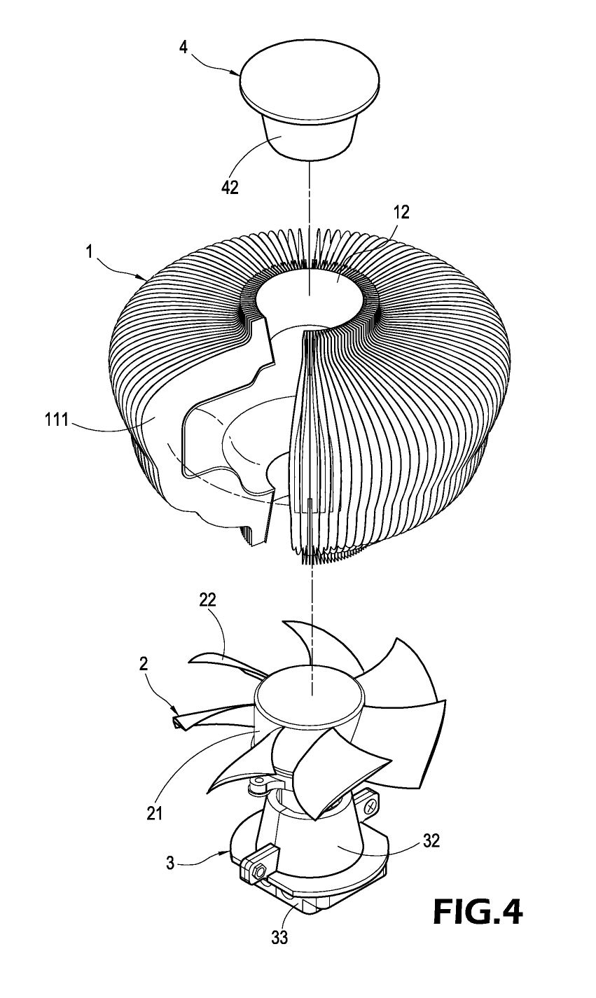

In the present invention, the semi-spherical bodies 11a and 11b are assembled by welding, boding or integrally forming into one piece to constitute the heat-dissipating body 1, and finally the bottom stand 3 and the top stand 4 are combined with each other to finish the structure of the heat dissipator. Alternatively, the plurality of heat-dissipating pieces 111 can be directly welded to the bottom stand 3 and the top stand 4 to form the heat-dissipating body 1. As shown in FIG. 4, the heat-dissipating body 1 can be integrally formed. The heat-dissipating body 1 is formed with a plurality of heat-dissipating pieces 111 by processing technique with an accommodating space 12 provided therein for accommodating the fan assembly 2. Finally, the heat-dissipating body 1 is combined with the bottom stand 3 and the top stand 4 to finish the structure of the heat dissipator.

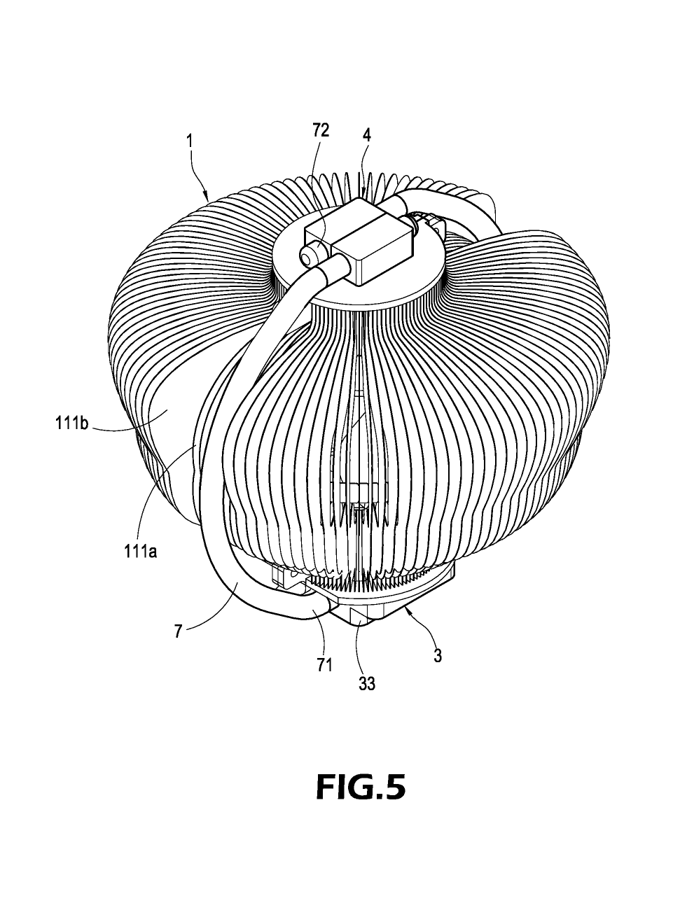

With reference to FIG. 5, it is a schematic view showing the structure of a further embodiment of the present invention. It can be seen from the drawing that the heat disspator is provided with at least one heat pipe 7. The heat pipe is circumferentially provided on the surface of the heat-dissipating body 1. Also, the outer periphery of each of the heat-dissipating pieces 111a adhered by the heat pipe 7 shrinks inwardly, so that the adhered heat-dissipating pieces 111a are substantially smaller than the heat-dissipating pieces 111b on both sides. As shown in the drawing, the heat pipe 7 seems to be accommodated in an accommodating tank. The heat pipe 7 has a heat absorbing end 71 and a condensing end 72. The heat absorbing end 71 and the condensing end 72 are provided on the bottom stand 3 and the top stand 4 of the heat dissipator, respectively. With this arrangement, owing to the working fluid and the capillary structure within the heat pipe 7, the heat source absorbed by the heat-conducting block 33 can be conducted to the top stand 4 and to each heat-dissipating piece 111 in a more rapid and uniform manner, thereby to perform the heat dissipation. Finally, with the airflow generated by the fan assembly 2, the heat-dissipating efficiency can be improved.

Although the present invention has been described with reference to the foregoing preferred embodiments, it will be understood that the invention is not limited to the details thereof Various equivalent variations and modifications can still be occurred to those skilled in this art in view of the teachings of the present invention. Thus, all such variations and equivalent modifications are also embraced within the scope of the invention as defined in the appended claims.

What is claimed is:

1. A heat dissipator for adhering on a heat-generating element, comprising:
a heat-dissipating body including a plurality of annular heat-dissipating pieces, the heat-dissipating body provided with a sealed accommodating space therein;
a bottom stand provided on a bottom of the heat-dissipating body and combined therewith, the bottom of the bottom stand adhering to the heat-generating element; and
a fan assembly provided within the sealed accommodating space of the heat-dissipating body, a bottom of the fan assembly having a connecting seat for connecting to the bottom stand to fix the fan assembly.

2. The heat dissipator according to claim 1, wherein the heat-dissipating body includes two corresponding semi-spherical bodies.

3. The heat dissipator according to claim 2, wherein the semi-spherical body includes a plurality of heat-dissipating pieces.

4. The heat dissipator according to claim 1, wherein an outer periphery of the heat-dissipating piece is formed into a curved shape.

5. The heat dissipator according to claim 1, wherein an outer periphery of the heat-dissipating piece is formed into a rectangular shape.

6. The heat dissipator according to claim 1, wherein an upper and a lower ends of the heat-dissipating body have a hollow connecting portion, respectively.

7. The heat dissipator according to claim 1, wherein a top of the heat-dissipating body is further provided with a top stand.

8. The heat dissipator according to claim 7, wherein the top stand is connected to the connecting portion.

9. The heat dissipator according to claim 7, wherein the top stand is further provided with a connecting pillar.

10. The heat dissipator according to claim 9, wherein the connecting pillar is connected to each heat-dissipating piece of the heat-dissipating body.

11. The heat dissipator according to claim 7, wherein the top stand includes two corresponding sub-stands.

12. The heat dissipator according to claim 11, wherein the two corresponding sub-stands are connected together by fastening elements.

13. The heat dissipator according to claim 7, wherein the top stand is integrally formed into one piece.

14. The heat dissipator according to claim 7, wherein the top stand has high heat conductivity.

15. The heat dissipator according to claim 1, wherein the bottom stand is further provided with a connecting pillar.

16. The heat dissipator according to claim 15, wherein the connecting pillar is connected to a connecting portion of the heat-dissipating body.

17. The heat dissipator according to claim 1, wherein the bottom stand includes two corresponding sub-stands.

18. The heat dissipator according to claim 17, wherein the two sub-stands are respectively provided with a plurality of protruding posts and holes with respective position corresponding to each other.

19. The heat dissipator according to claim 1, wherein the bottom stand is integrally formed into one piece.

20. The heat dissipator according to claim 7, wherein the bottom stand has high heat conductivity.

21. The heat dissipator according to claim 1, wherein a bottom of the bottom stand is further provided with a heat-conducting block.

22. The heat dissipator according to claim 1, wherein a direction of airflow generated by the fan assembly is downward.

23. The heat dissipator according to claim 1, wherein the connecting seat of the fan assembly is sandwiched in the bottom stand.

24. The heat dissipator according to claim 1, wherein the connecting seat of the fan assembly is provided with a plurality of positioning holes.

25. The heat dissipator according to claim 24, wherein the bottom stand has protruding posts penetrating through the positioning holes, respectively.

26. The heat dissipator according to claim 1, wherein the heat dissipator further comprises at least one heat pipe.

27. The heat dissipator according to claim 26, wherein the heat pipe is circumferentially provided on an outer periphery of the heat dissipator.

28. The heat dissipator according to claim 26, wherein heat-dissipating pieces adhered by the heat pipe are substantially smaller than heat-dissipating pieces on both sides.

29. The heat dissipator according to claim 26, wherein both ends of the heat pipe are provided within the bottom stand and the top stand, respectively.
